(19) United States
(12) Patent Application Publication
(10) Pub. No.: US 2002/0024104 A1
(43) Pub. Date: Feb. 28, 2002

(54) Chip carrier socket

(76) Inventor: Brian D. Earl, South Bend, IN (US)

Correspondence Address: BAKER & DANIELS, 205 W. JEFFERSON BOULEVARD, SUITE 250, SOUTH BEND, IN, 46601, US

(21) Appl. No.: 09/839,257

(22) Filed: Apr. 20, 2001

Related U.S. Application Data
(60) Provisional application No. 60/198,559, filed on Apr. 20, 2000.

(51) Int. Cl. H01L 29/76

(52) U.S. Cl. 257/378

(57) ABSTRACT

A test socket for an integrated circuit package includes a base for receiving the package, a pressure application subassembly which is pivotally rotated relative to the base portion, and a latching subassembly which is pivotally mounted to the opposite end of the base. The pressure application subassembly includes a plurality of trusses which pivot at one end about trunnions mounted to the base of the socket. The trusses carry spring-loaded rocker arms which hold the integrated circuit package in place. The socket also includes means for aligning the integrated circuit along one edge thereof and about its centerline.

### BACKGROUND OF THE INVENTION

1. Field of the Invention

This invention relates to a chip carrier socket, and in particular, to one for burn-in applications.

2. Brief Description of the Prior Art

Integrated circuits, or chips, must be tested after their manufacture, normally at elevated temperatures, which is the so-called “bum-in process.” The integrated circuits are temporarily installed on a circuit board, tested, and then removed from the circuit board and shipped. Accordingly, sockets are necessary to install the integrated circuits on the printed circuit board for testing. These sockets must include multiple contacts to connect each of the terminals of the integrated circuit chip to corresponding conductors in the circuit board. Since the sockets are used repeatedly in high volume integrated circuit chip manufacture, it is desirable that the sockets be durable and capable of reliable, repeated operation.

These sockets are positioned on a burn-in board where the sockets are arranged in a relatively dense array to allow for many integrated circuits to be burned in at once. These sockets are therefore arranged in relatively close side-by-side and end-to-end spacing. This oftentimes makes the operation of the bum-in process more difficult, because the operator must be able to physically reach the sockets to open and close them.

It is also desirable that the chip carrier sockets be capable of conforming to a large tolerance of chip thicknesses. Chip manufacturing may result in a large tolerance of chip thickness. For example, some chips are nominally 0.042 inches thick, but can have a tolerance of +or −10% of nominal thickness. One of the socket types which performs this burn-in function includes a base portion, a cover member which rotates about one side edge of the base by way of a hinge, and a latch member opposite the hinge side, which holds the cover and base together. The large tolerance in chip thicknesses causes great disparity in contact pressure between the contacts of the socket and the contact sections of the chip. For example, if the chip is on the high tolerance side, then the cover member causes greater pressure on the contacts which are proximate the hinge side, and lesser contact pressure adjacent to the latch side. The opposite effect occurs when the chip is on the lower tolerance side. The contact pressure across the contacts should be relatively uniform to ensure that the test is properly conducted and that the chip is working properly.

During testing, a plurality of sockets are typically positioned on bum in boards, and the boards placed one above the other in ovens. Thus, the overall height of the sockets can drastically affect the number of boards installed in any given cycle.

### SUMMARY OF THE INVENTION

In one embodiment of the invention, an integrated circuit socket includes a base, a plurality of electrical contacts in the base, a pressure application subassembly including a plurality of pressure application members for applying downward force on an integrated circuit, and a latching assembly to retain the pressure application members in place. The pressure application members may be in the form of spring-loaded rocker arms. The rocker arms have surfaces for applying pressure to the integrated circuit. The pressure application subassembly may further include truss members pivotally connected to the base. The pressure application members may be connected to the truss members.

In another embodiment of the invention, the pressure application subassembly includes rocker arms that urge pressure application members against an integrated circuit. The pressure application members may be pads having cavities for receiving ends of the rocker arms. The pads may be removable.

In another embodiment of the invention, an integrated circuit socket includes a base, a first locator plate connected to the base, a pair of flexible arms connected to the first plate, a second locator plate connected to the base and a cover movable between an open position and a closed position. Movement of the cover from the open position to the closed position causes the first and second plates and the arms to move so as to contact an integrated circuit in the socket, thereby positioning the integrated circuit. The socket may include camming members connected to the base. Movement of the first plate in a first direction causes a portion of the arms to contact the camming members and move toward the integrated circuit.

These and other features of the present invention will be apparent to those of skill in the art from the following detailed description and the accompanying drawings.

### BRIEF DESCRIPTION OF THE DRAWINGS

FIG. 1 is a perspective view of an integrated circuit test socket according to one embodiment of the present invention in the fully closed position.

FIG. 2 is a perspective view of the socket of FIG. 1 showing one of the latch arms broken away to view the pressure application subassembly of the socket in greater detail.

FIG. 3 is a perspective view of the lower base portion of the socket of FIG. 1.

FIG. 4 is a perspective view of a portion of the latch subassembly of the socket of FIG. 1.

FIG. 5 is a perspective view of a truss member of the pressure application subassembly of the socket of FIG. 1.

FIG. 6 is a perspective view of the front and rear pinion assembly about which the cover of the socket shown in FIG. 1 rotates.

FIG. 7 is a perspective view of a rocker arm which is a portion of the pressure application subassembly of the socket of FIG. 1.

FIG. 8 is a cross sectional view through lines 8-8 of FIG. 1 showing the latch subassembly in the fully locked position.

FIG. 9 is a view similar to that of FIG. 8, showing the handle rotated 30 degrees.

FIG. 10 is a view similar to that of FIGS. 8 and 9, showing the handle rotated 60 degrees, at which point the handle begins to rotate the latch hook.

FIG. 11 is a view similar to that of FIGS. 8 through 10 showing the handle rotated to its full stop position, at which point the latch hook is clear from its associated latching member.

FIG. 12 is a view similar to that of FIG. 11 showing the pressure application subassembly beginning to rotate in the counter clockwise position.

FIG. 13 is a view through lines 13-13 of FIG. 1, but shown in the position of FIG. 11.

FIG. 14 is a perspective view of another embodiment of an integrated test socket according to the present invention in the fully closed position.

FIG. 15 is a perspective view of a rocker arm that forms a component of the embodiment of FIG. 14.

FIG. 16 is a perspective view of a pressure pad that forms a component of the embodiment of FIG. 14.

FIG. 17 is a perspective view of a truss member that forms a component of the embodiment of FIG. 14.

FIG. 18 is a sectional view taken along line 18-18 in FIG. 14 and showing the latch subassembly in the open position.

FIG. 19 is a partially cut-away, perspective view of the latch subassembly that is a component of the embodiment of FIG. 14.

FIG. 20 is a sectional view taken along line 20-20 in FIG. 14.

FIG. 21 is a perspective view of the embodiment of FIG. 14 with the latch subassembly and pressure application subassembly positioned away from the device to be tested.

FIG. 22 is a top plan view of the device as shown in FIG. 21.

FIG. 23 is a top plan view of the device as shown in FIG. 21 with the latch subassembly partially closed.

FIG. 24 is a top plan view of the device as shown in FIG. 21 with the latch subassembly closed further.

FIG. 25 is a perspective view of an alternative embodiment of a pinion assembly that is a component of the present invention.

### DETAILED DESCRIPTION OF EMBODIMENTS OF THE INVENTION

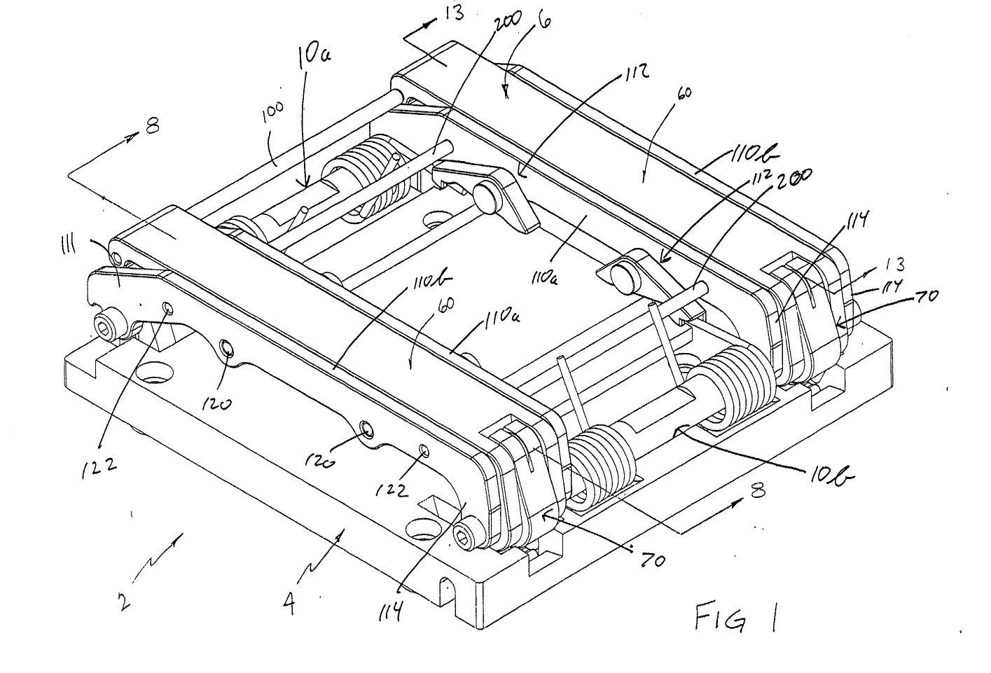

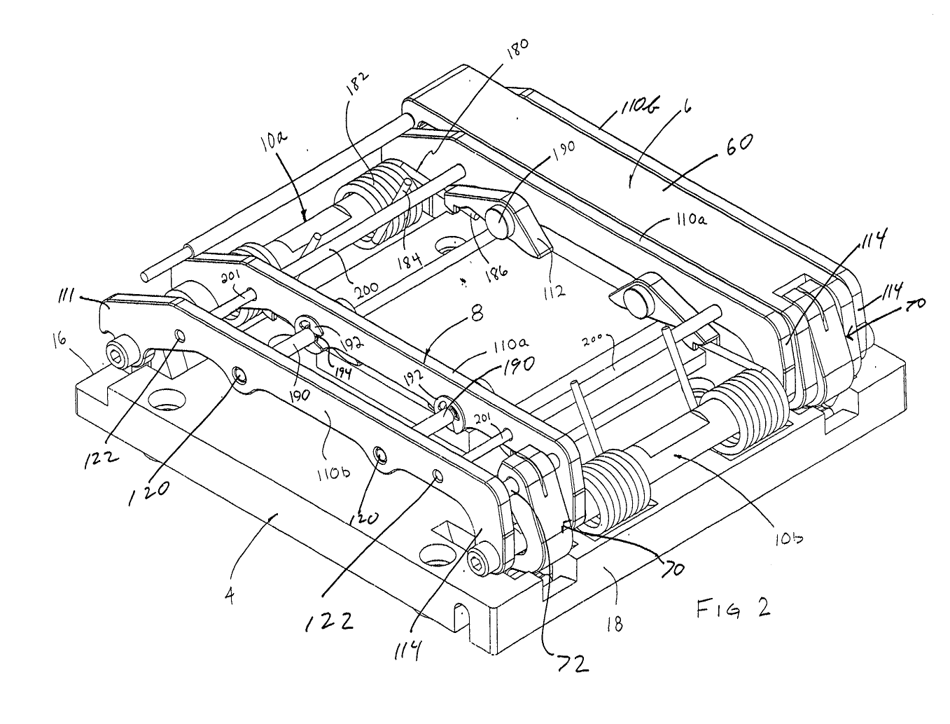

With respect first to FIGS. 1 and 2, an integrated circuit socket 2 according to one embodiment of the present invention generally includes a base 4, a latch subassembly 6, a pressure application subassembly 8 and pinion assemblies 10a and 10b.

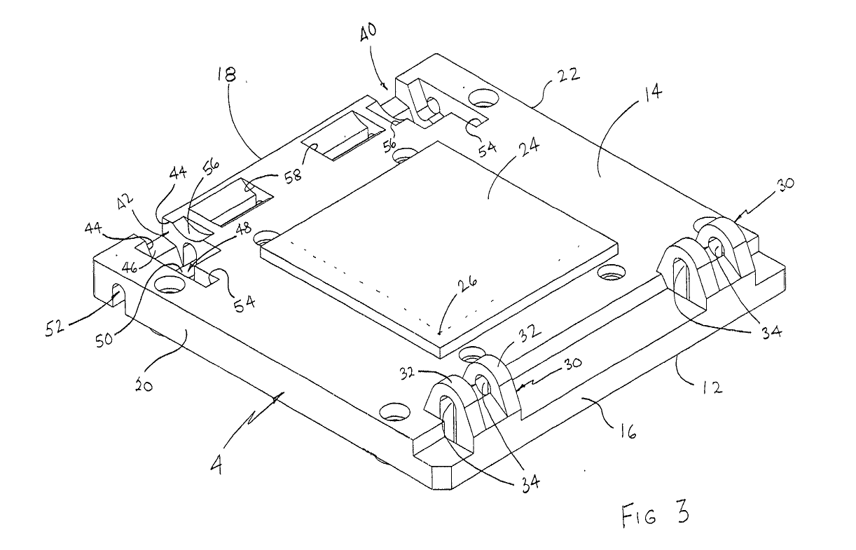

As shown in FIG. 3, base 4 includes a lower face 12 which would be placed adjacent to a printed circuit board, or burn-in board, on which the socket would be mounted. Base 4 further includes an upper face 14, a rear edge 16, a front edge 18, and side edges 20 and 22. A chip receiving area 24 is located on face 14 and includes a plurality openings 26 (only one of which is shown) extending completely through base 4. A plurality of contacts (not shown) extend through openings 26 and make a connection between the contacts of the chip and the burn-in board as is well known in the art.

Base 4 also includes trunnions 30 for connecting pressure application subassembly 8 to base 4, as described below. Trunnions 30 generally include a pair of U-shaped members 32 having openings 34 therethrough. Openings 34 receive pinion subassemblies 10a and 10b, as described below.

Base 4 further includes a latching area shown generally at 40 having an opening at 42 defined by sidewalls 44 and surface 46. The latching area 40 is further defined by a recessed section 48 having a lower surface 50. An opening 52 extends completely through base 4 between side edges 20 and 22. Latching area 40 also includes three pairs of openings 54, 56, and 58, which will be described in further detail below.

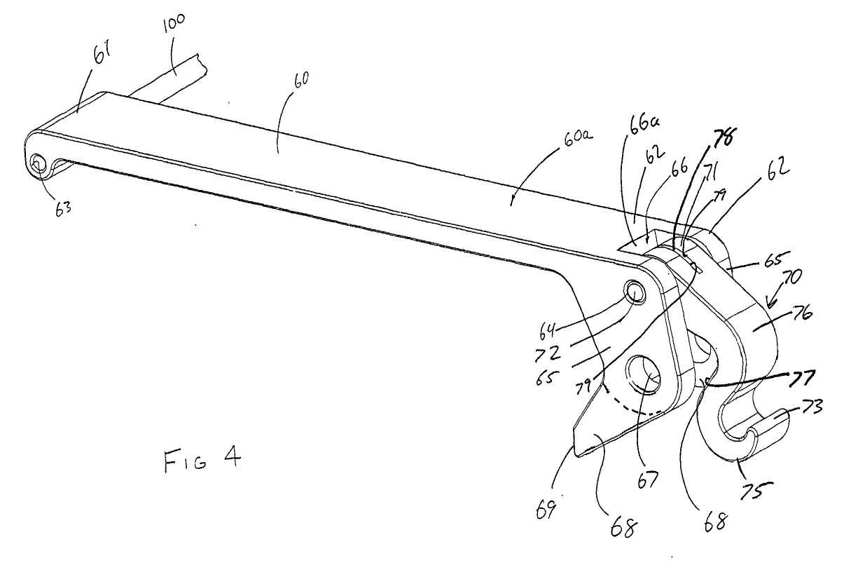

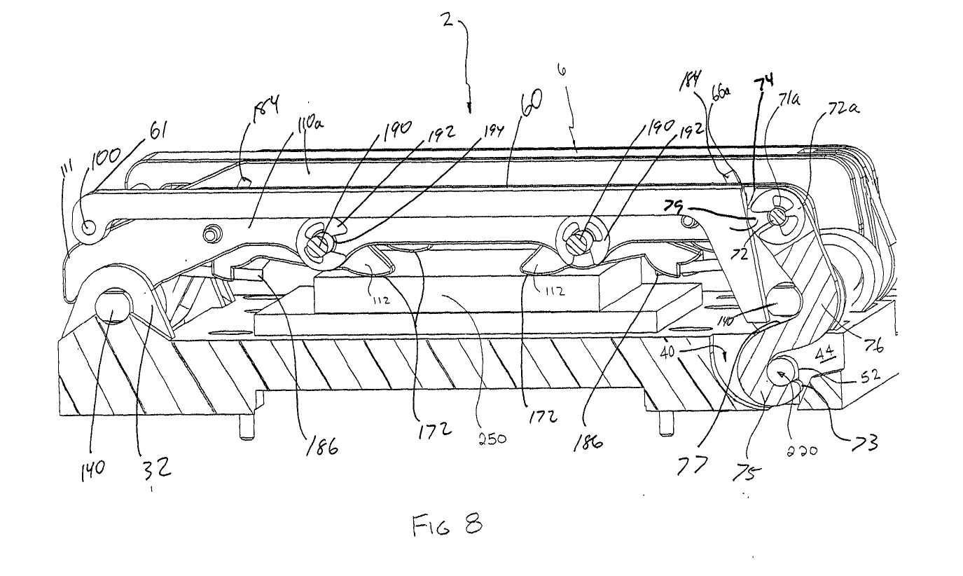

With reference now to FIGS. 4 and 8, a portion of latching subassembly 6 will be described. In this portion of latching subassembly 6, a handle 60 includes a first end 61 and a second end 62. A first opening 63 extends through first end 61 and a second opening 64 extends through second end 62. A pair of ears 65 extends from second end 62 so as to define a space 66 therebetween. Space 66 includes a rear surface 66a. An opening 67 extends through ears 65. One ear 65 includes an end 68 having a camming surface 69. The latching subassembly 6 further includes a hook 70 having a first end 71 pivotably secured to ears 65 by a pin 72 extending through opening 64. Hook 70 further includes a second end 73 opposite first end 71. Hook 70 has a flattened rear surface 74 (FIG. 8) and a lower hook section 75. The hook 70 is somewhat serpentine in configuration, thereby defining an intermediate arcuate section 76 having an inner surface at 77. The first end 71 of the hook 70 is slotted at 78, thereby defining parallel inner side surfaces 79. The first end 71 of the hook 70 also includes an opening 71a which coincides with openings 64, and receives pins 72 therethrough. As shown best in FIG. 8, clip 72a is receivable in slot 78 and engages pin 72, thereby retaining hook 70 to the handle member 60. As shown in FIGS. 1 and 4, the latch subassembly 6 includes two portions as just described interconnected via an intermediate rod 100. It should be appreciated that the rod can be secured in openings 63 by adhesive, a threaded connection or other means.

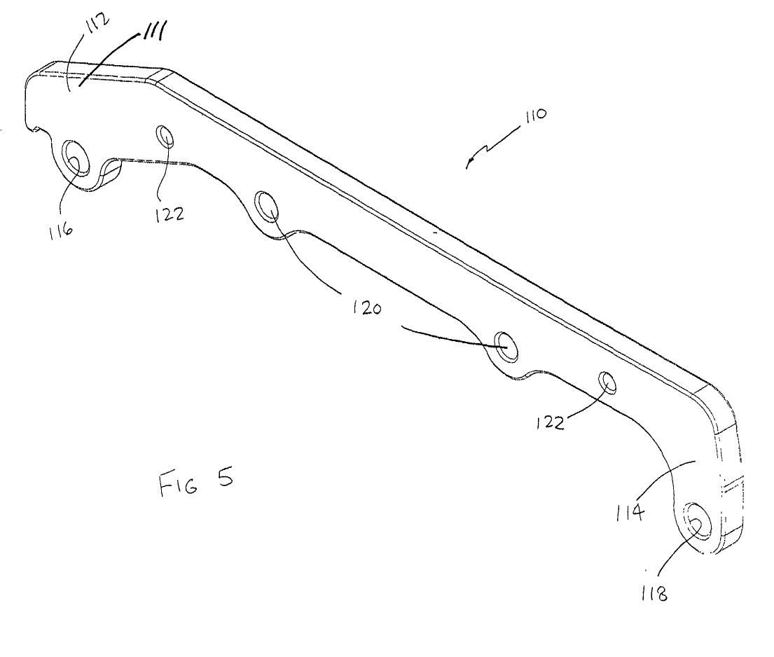

As shown best in FIG. 2, the pressure application subassembly 8 generally includes a pair of inner and outer truss members 110a and 110b, pinion assemblies 10a and 10b, and pressure application member 112. It should be appreciated that the two truss members 110a and 110b are identical in nature, and therefore will be described in FIG. 5 by reference numeral 110.

As shown in FIG. 5, the truss members 110 are elongated members having a first end 111 and a second end 114. First end 111 has an opening 116 and second end 114 has an opening 118. The truss members 110 also include two pairs of openings 120 and 122.

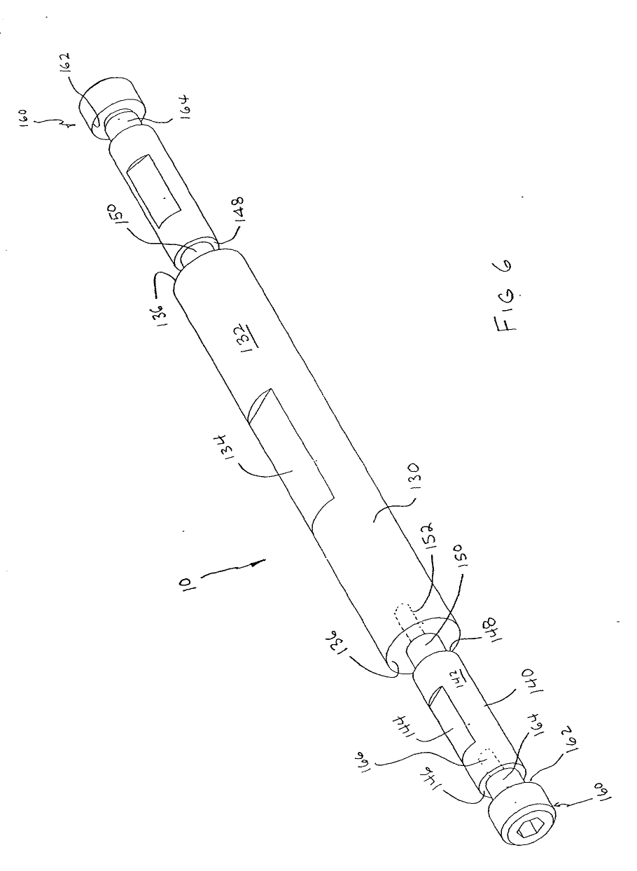

As described above, the pressure application subassembly 8 also includes identical pinion assemblies 10a and 10b, which will be described in detail with reference to FIG. 6 as reference numeral 10. The pinion assembly 10 includes a center section 130 having a cylindrical surface 132 and flats 134 intermediate its opposite ends 136. The pinion assembly 10 further includes end sections 140 having a cylindrical surface 142 and a second pair of flats 144. The end sections 140 further include end surfaces 146 and 148 with a journal 150 extending from the end surface 148. Journal 150 includes a threaded member 152 which cooperates with a threaded bore extending into end surface 136 of section 130. Cap screws 160 are provided at each end. Each cap screw 160 has a surface 162, a journal section 164, and a threaded section 166 which cooperates with a threaded bore extending into end surface 146.

When assembled, ends 111 of two truss portions are located between end surfaces 136 and 148 and 146 and 162, with the journals 150 and 164 positioned in openings 116. The same is true at the opposite end 114 of the truss member 110, where the ends 114 are located between surfaces 136 and 148 and 146 and 162 with the journals 150 and 164 positioned in respective openings 118. The pinion sections 140 are profiled such that the outer surfaces 142 fit in the openings 34 of the trunnions 30 at end 111, as well as the openings 67 of the handles 60.

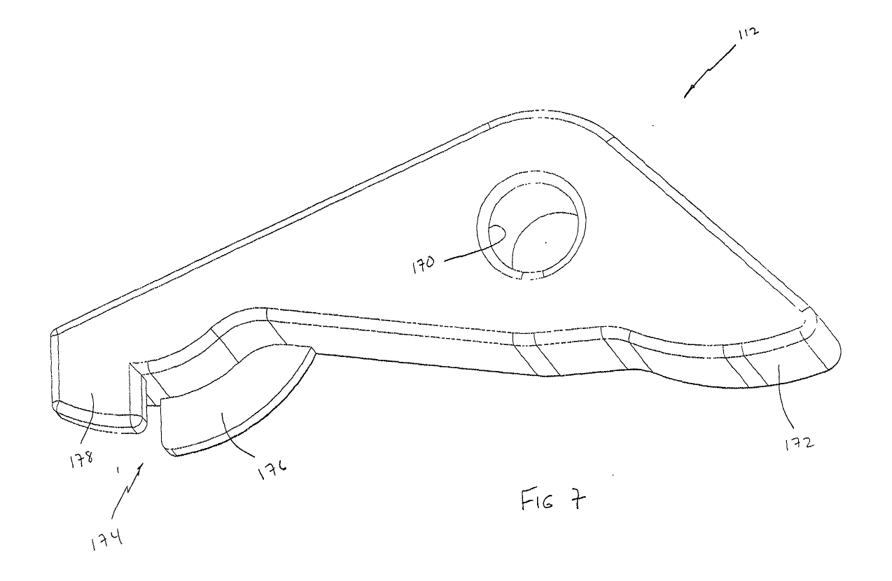

With respect to FIGS. 2 and 7, the pressure application subassembly 8 includes pressure application members 112. In the embodiment shown, pressure application members 112 are rocker arms which are rotatable about an opening 170. Rocker arms 112 include pressure application points 172. The opposite ends 174 of the rocker arms 112 include a spring receiving section defined by offset and parallel plates 176 and 178. The pressure application subassembly 8 further includes torsion springs 180 having central wound sections 182 and ends 184 and 186. Ends 186 are located in end 174 of rocker arm 112 between plates 176 and 178. The rocker arms 112 are connected to the trusses 110 by the use of pins 190 and clips 192 located in slots 194. Stops 200 span inner trusses 110a. Ends 184 of springs 180 contact stop 200, thereby limiting the pivotal movement of the rocker arm 112.

The socket 2 is assembled as follows: The two inner truss members 110a are assembled to the stops 200 by inserting the ends 201 of the stops 200 through the openings 122. The latch subassembly 6 is positioned over the inner and outer truss assemblies 110a and 110b such that the openings 67 are aligned with the openings 118 in the trusses 110a and 110b. The pinion section 130 of the pinion assembly 10b, together with the associated springs 180, is positioned intermediate the two inner trusses 110a and the journals 150 are positioned through the openings 118 into the openings 67 such that the threaded ends 152 engage their respective threaded openings in the pinion section 130. The cap screws 160 are positioned with the journals 164 in the openings 118 of the outer trusses 110b. The threaded member 166 is engaged with its associated threaded opening. This combination of the trusses 110a, 110b and latch subassembly 6 is positioned adjacent to the base 4 such that the openings 116 are aligned with openings 34 in the trunnions 30. The pinion section 130, together with the associated torsion springs 180, is placed intermediate the trusses 110a and the pinion sections 140 are inserted from both ends of the trunnions into openings 34 such that the threaded end 152 extending from the journal 150 is threaded into the end of the section 130. It should be appreciated that during this assembly, the ends 184 of springs 180 are positioned above the stops 200 while the ends 186 are positioned below the stops 200. The rocker arms are installed adjacent the inner surfaces of the inner truss members 110a by placing the pins 190 through openings 170 in rocker arms 112 and through openings 120. Handles 60 can be rotated to provide access to the space intermediate the two trusses 110a and 110b to assemble the clips 192 to retain the rocker arms 112 to the inner truss members 110a. As mentioned above, the truss members 110a and 110b are installed such that the ends 186 of the torsion springs 180 are trapped between the two plates 176 and 178 of the rocker arms 112 to keep ends 186 aligned with the rocker arms 112. To complete the assembly, a counter latching member 220, shown as a cylindrical rod, is positioned in opening 52 between the side edges 20 and 22 of base 4 and affixed in placed by means known to those skilled in the art. The rod 220 can be any material sufficient to withstand the forces anticipated. Rod 220 is preferably steel.

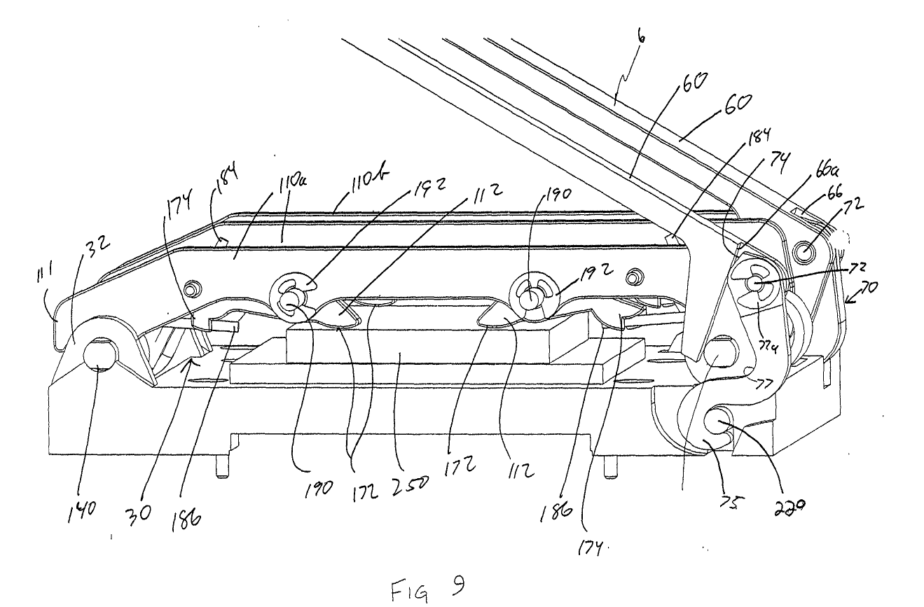

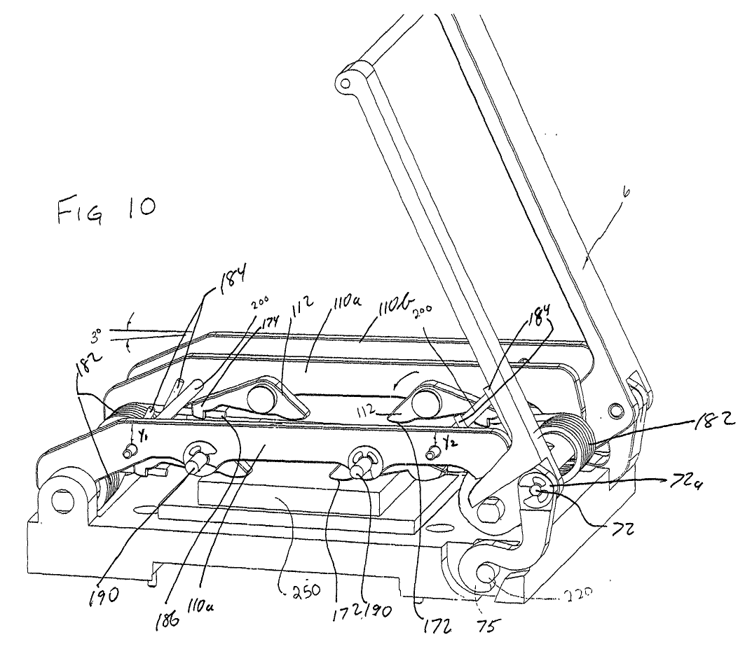

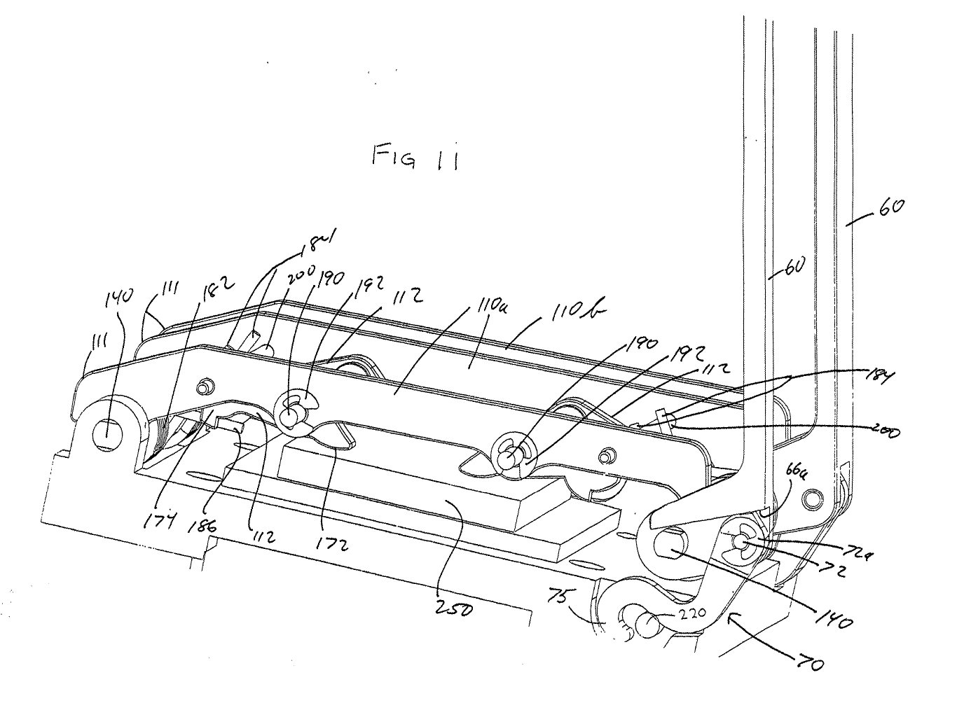

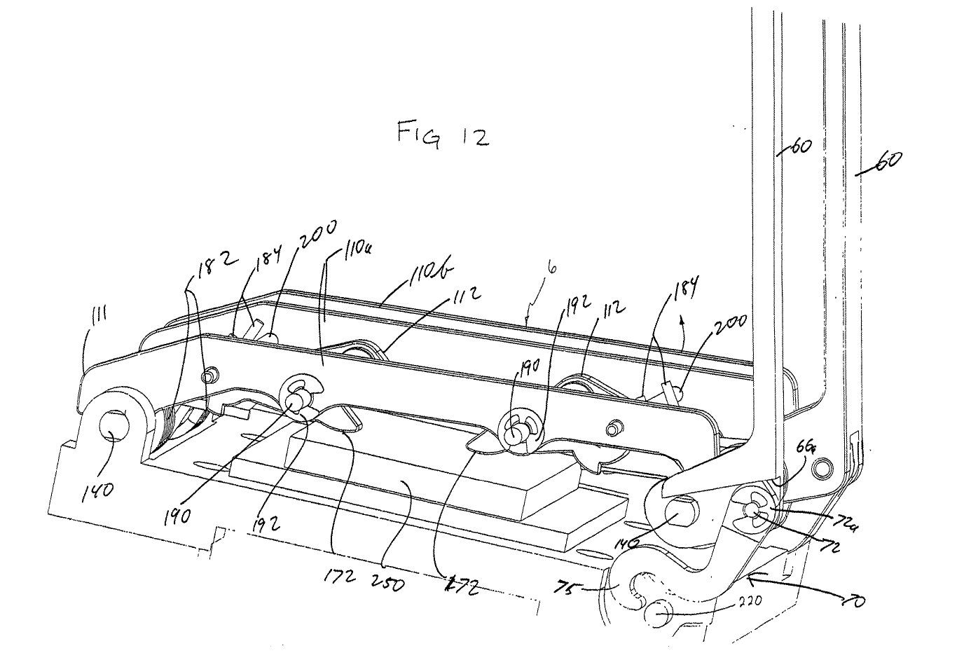

With respect now to FIGS. 8 through 12, the operation of the assembled device will be described in detail. In FIG. 8, the socket 2 is shown with a device 250 to be tested in position. The latch subassembly is fully locked with the hook sections 75 engaging the counter latch member 220. The serpentine shape of the hook 70, and particularly the section 76, bypasses the pinion assembly 10b such that no interference is presented. As shown in FIG. 9, as the latch subassembly 6 is rotated, inner surface 77 moves away from pinion assembly 10b. The hook section 75 is still engaging the counter latch member 220. With reference now to FIG. 10, further rotation of the latch subassembly 6 causes engagement between surfaces 66a and 74. This causes rotation of hook section 75 away from the counter latch member 220 as shown in FIG. 11. FIG. 12 shows the hook section 75 clear of the counter latch member 220 allowing the entire assembly 6 to rotate in the counterclockwise direction as viewed in FIG. 12. It should be appreciated that rotating subassembly 6 in the opposite direction secures device 250 in place. Note that when subassembly 6 is fully closed, rocker arms 112 apply pressure to the device 250 to hold it in place. Because each of the rocker arms 112 are rotatable independently of one another and are independently spring loaded, they can adjust to different thicknesses of device 250.

With reference to FIG. 10, in one embodiment of the invention, the stops 200 adjacent ends 114 of truss member 110a and 110b are spaced slightly closer to the upper surface of truss member 110a and 110b than are the stops 200 adjacent ends 111. That is, the distance Y2 is less than the distance Y1. This spacing allows for further counter-clockwise rotation of the forward most rocker arms 112 as shown in FIG. 10. In this embodiment of the invention, the stops 200 are tuned such that, when the angle of the pressure application subassembly 8 is within three degrees of closure, the tips of all of the rocker arms 112 simultaneously hit the top of the circuit to be tested. This allows for continuous and consistent pressure on device 250.

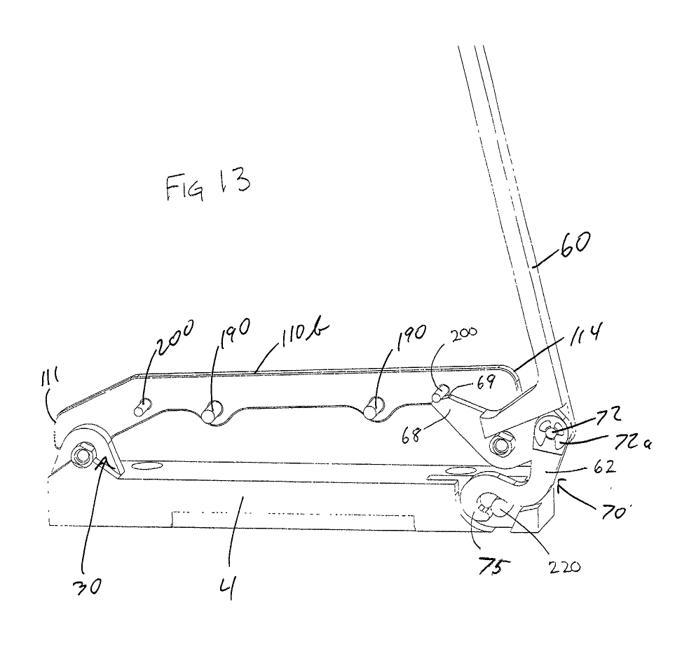

Note also that stops 200 limit rotation of the latch subassembly 6. As shown in FIG. 13, when the latch subassembly 6 is rotated to the position where the hook section 75 clears the corresponding latch element 220, the surface 69 abuts the stop 200 preventing further rotation.

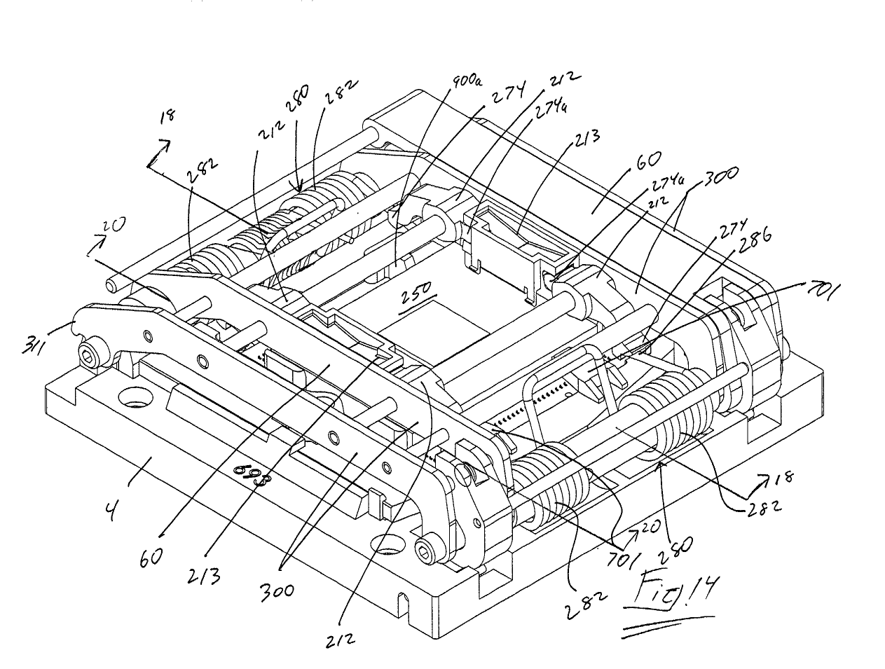

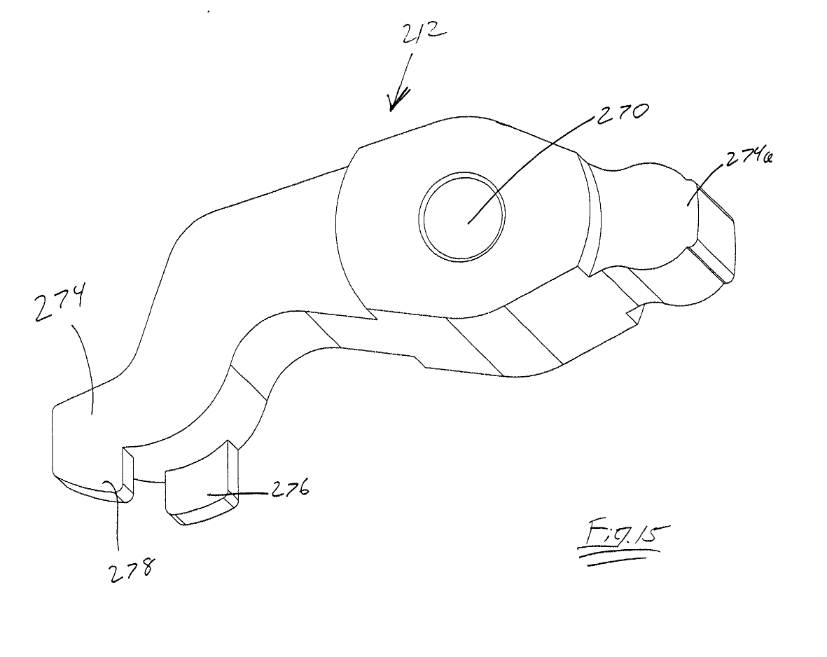

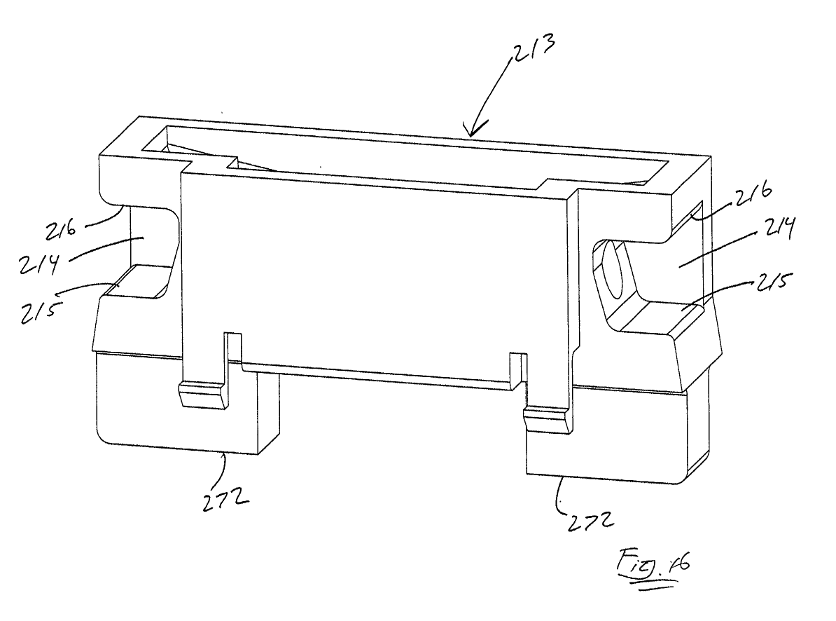

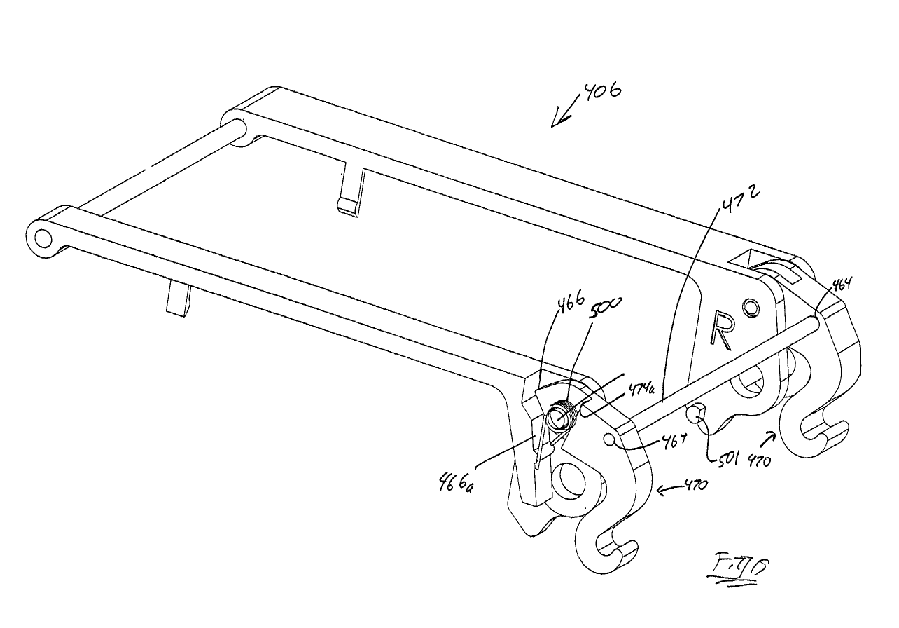

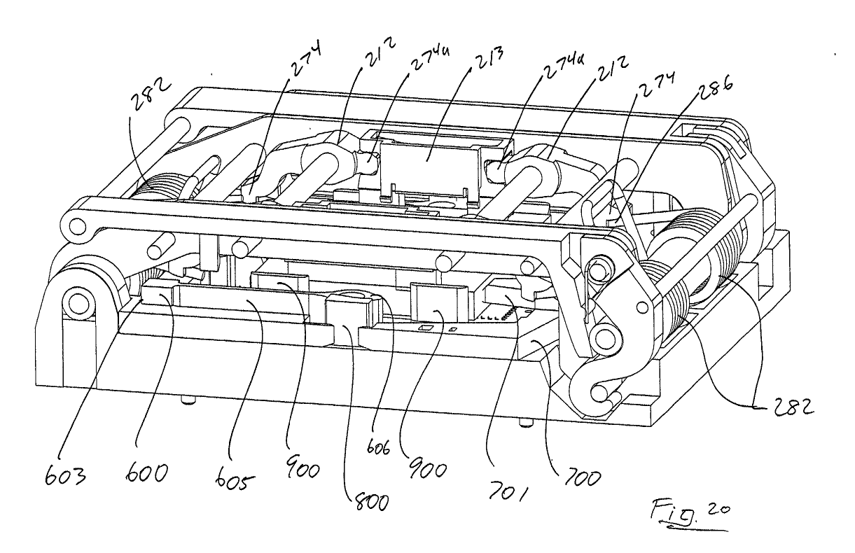

FIGS. 14 through 24 show an alternative embodiment of the present invention. In this embodiment, pressure application members 112 are in the form of rocker arms 212 and pressure pads 213. Like rocker arms 112, rocker arms 212 are rotatable about an openings 270 and include ends 274 having a spring receiving section defined by offset and parallel plates 276 and 278. Rocker arms 212 also include ends 274a. Pads 213 include cavities 214 having first surfaces 215 and second surfaces 216. Pads 213 further include pressure applications surfaces 272.

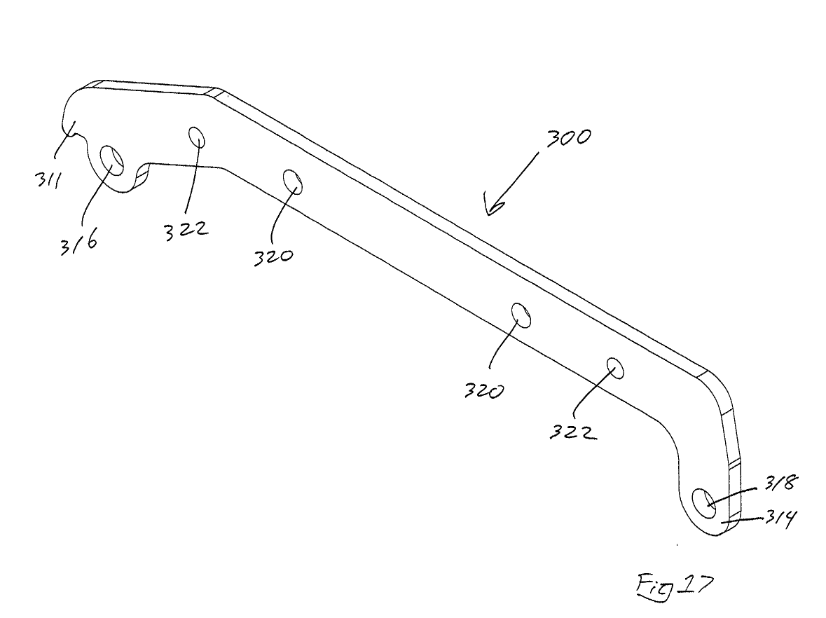

FIGS. 14 and 17 show an alternative embodiment of truss member 110 for use with rocker arms 212 and pads 213. In this embodiment, indicated by reference numeral 300, openings 316, 318 320 and 322 correspond to openings 116, 118, 120 and 122 in truss member 110. Truss members 300 also include ends 311 and 314. Note also that torsion spring 180 has been replaced with a torsion spring 280 having two wound portions 282 and two ends 286.

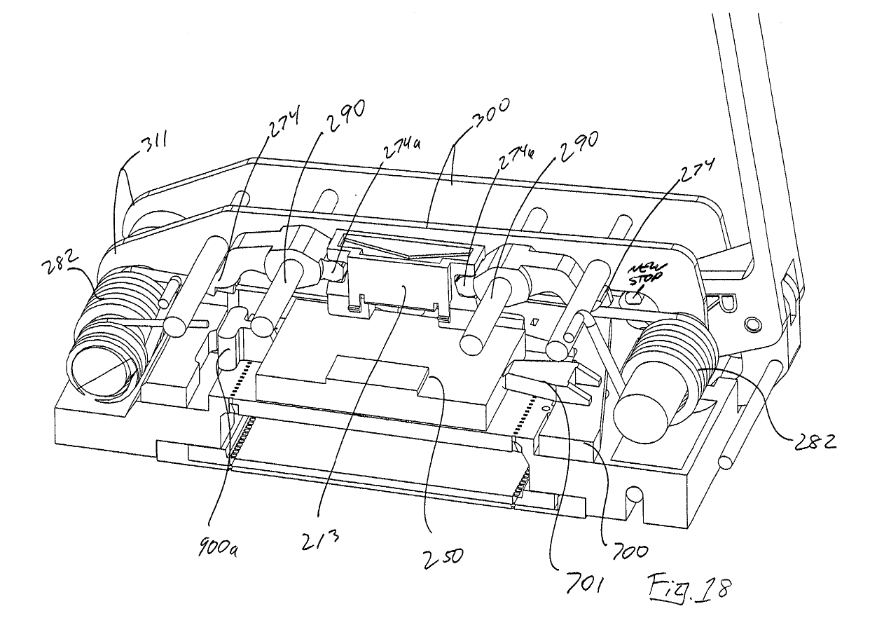

As shown in FIGS. 14 and 18, rocker arms 212 are connected to truss members 300 by pins 290 extending through openings 320 and openings 270. Note that in the embodiment shown, pins 290 extend through two rocker arms 212 and all four truss members 300. Ends 274a are located in cavities 214 of pads 213. When the device is in the latched position shown in FIG. 14, spring ends 286 of springs 280 bias ends 274 upwardly. This causes end 274a to put a downward force on surface 215 of pad 213. This in turn causes surfaces 272 to put a downward force on the device 250 to be tested, thereby holding it in place. Operating handles 60 to unlatch the device releases the pressure in a manner similar to that of the embodiment of FIGS. 1 through 13. Note that with this embodiment of the invention, pads 213 are removable. Thus, different size pads 213 may be utilized to accommodate different chips of varying thickness.

Note that in the embodiment of the invention using torsion springs 80 and rocker arms 112, as well as the embodiment using torsion springs 280 and rocker arms 212 in connection with pads 213, the hold down force applied to the device varies less over a wider range of chip thickness than does the hold down force of prior art devices that utilize compression springs to apply force to the device. This is because the torsion springs apply an indirect force to the device through a lever like interaction with the rocker arms. Note also that the sockets of the present invention include a relatively large open space or window above the device to be tested. This allows easy access to the surface of the device, which is useful for attaching thermocouples, heat sinks or other instruments.

The embodiment of FIGS. 14 through 24 also includes an alternative latch subassembly 406. In this embodiment, a rod 472 extends though openings 464 in both hooks 470. In this embodiment, the ends of rod 472 are knurled and are press fit in openings 464. Note also that a torsion spring 500 positioned in space 466. Springs 500 are positioned so as to contact surfaces 466a and surfaces 474a of hooks 470. Spring 500 provides and additional biasing force on hook 470 for more secure latching. In this embodiment of the invention, latching subassembly 406 includes a stop member 501 for limiting rotation of subassembly 406 in the clockwise direction as viewed in FIG. 18. As shown in that figure, rotation of subassembly 406 in the clockwise direction will ultimately cause stop 501 to contact truss member 210, thereby preventing further movement

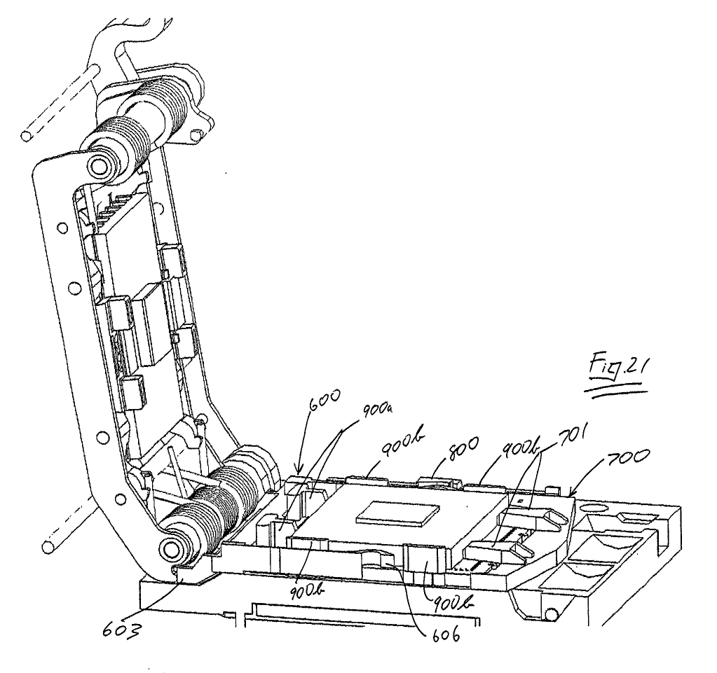

FIGS. 21 through 24 illustrate a centering mechanism, which is another feature of the present invention. The centering mechanism generally includes a rear locator plate 600, a front locator plate 700, camming members 800, rear locators 900a and coarse locators 900b. Rear locator plate 600 includes a pair of side locators 602, a first end 603 and a second end 604. Side locators 602, in the embodiment shown, are a pair of flexible arms 605 having enlarged ends 606. Front locator plate 700 includes a pair of front locators 701 and a first end 702. Plates 600 and 700 are biased toward ends 311 of truss members 300 by springs 901. Note that in the figures, the springs 901 are only visible for front locator plate 700. A second pair of springs 901 is located below plate 600. Camming members 800 are formed on base 4 and included a straight segment 801 and an angled segment or ramp 802. Coarse locators 900a and 900b are also formed on or connected to base 4. Coarse locators 900a and 900b are stationary.

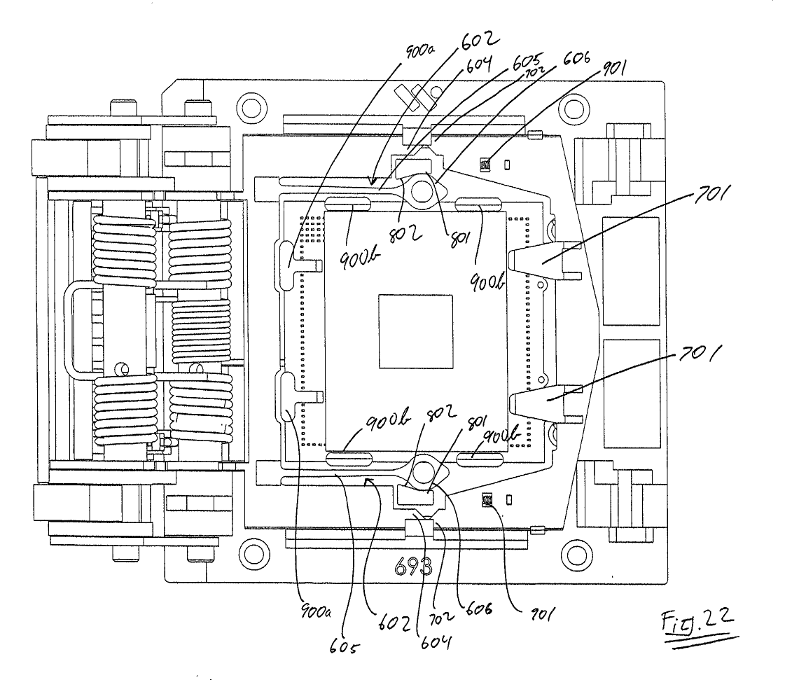

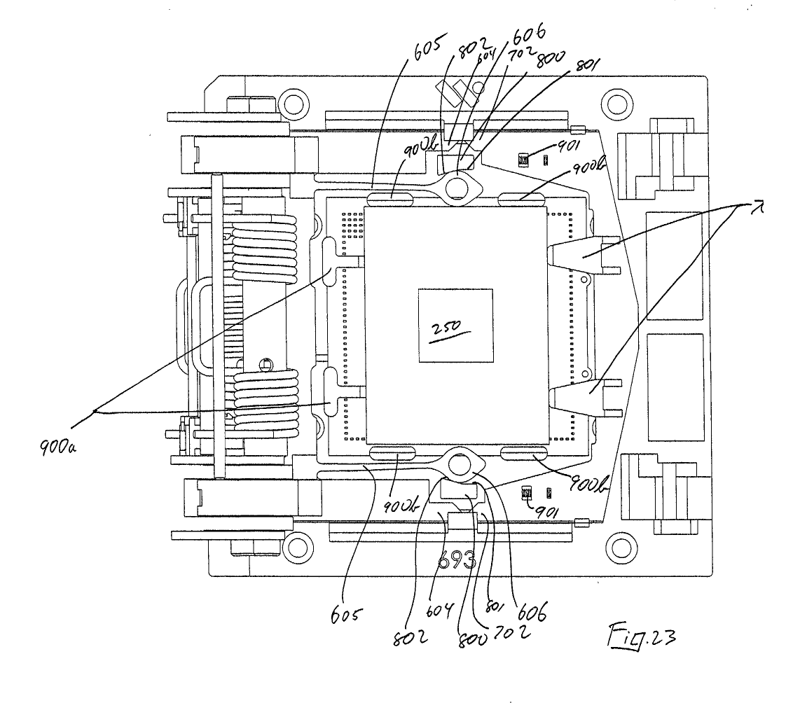

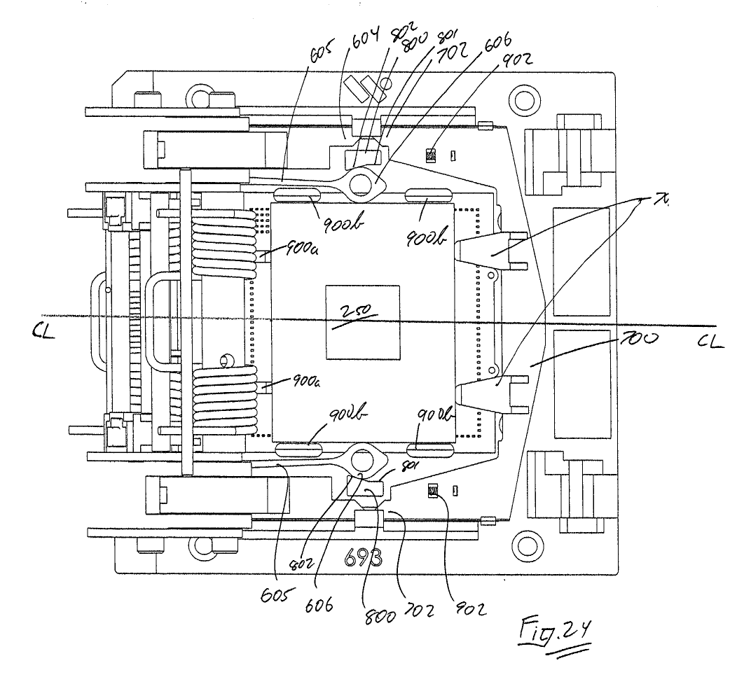

In use, rotating subassembly 406 to the position shown in FIG. 21 causes end 311 of truss 300 to contact end 603 of plate 600 and push plate 600 toward end 314. This in turn causes plate 600 to push plate 700 in the same direction by contact of ends 604 and 702. The device 250 to be tested may then be inserted between locators 701, 900a and 900b (FIG. 22). As the subassembly 406 is rotated toward the latched position, plates 600 and 700 begin to move toward ends 311 under the force of springs 901. As this occurs, locators 701 contact device 250 and push it into contact with locators 900a, thereby aligning device 250 along one edge. In this position, plate 700 cannot move any closer to ends 311. As plate 600 moves toward ends 311, ends 606 of arms 605 move toward angled surfaces 802 of camming members 800, thereby causing arms 605 to flex inwardly and contact the sides of device 250 (FIG. 23). Further rotation of the subassembly 406 causes ends 606 to move further along surfaces 802 and further toward the device 250, thereby aligning device 250 along centerline CL (FIG. 24).

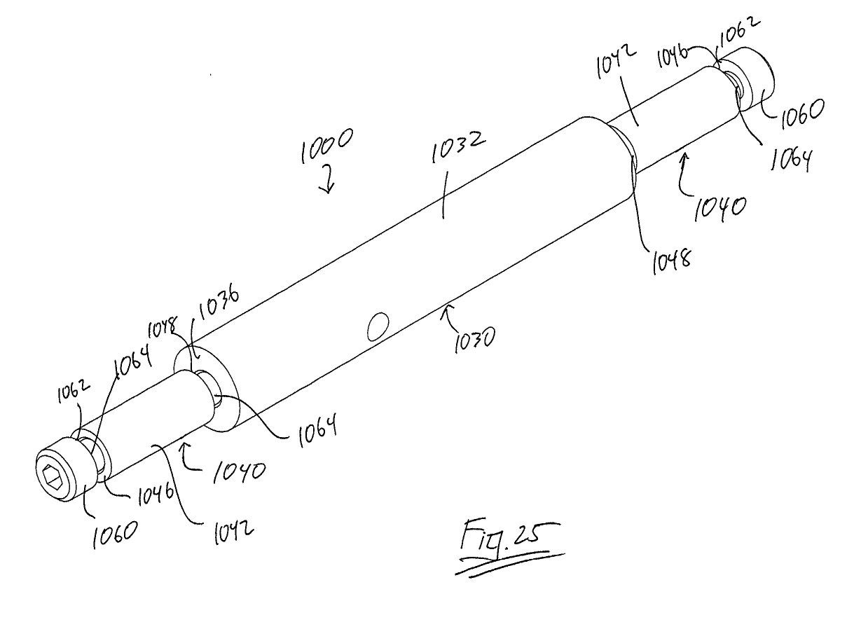

FIG. 25 shows an alternative embodiment of the pinion assemblies. In this embodiment, pinion assembly 100.0 includes a center section 1030 having a cylindrical surface 1032 and opposite ends 1036. The pinion assembly 10 further includes sleeves 1040 having a cylindrical surface 1042. Sleeves 1040 further include end surfaces 1046 and 1048. Cap screws 1060 are provided at each end. Each cap screw 160 has a surface 162 and a journal section 1064. Journal sections 1064 extend completely through sleeves 1040 and are threaded into the ends of section 1030. Pinion assembly 1000 is assembled to the socket in the same manner as described above for pinion assembly 10.

Although the present invention has been shown and described in detail, the same is by way of example only and not a limitation on the scope of the invention. Numerous changes can be made to the embodiments described without departing from the scope of the invention.

1. An integrated circuit socket, having:
a base;
a plurality of electrical contacts in the base;
a pressure application subassembly including a plurality of pressure application members for applying downward force on an integrated circuit; and
a latching assembly.

2. The socket of claim 1, wherein the pressure application members are spring-loaded.

3. The socket of claim 1 wherein the pressure application members include rocker arms.

4. The socket of claim 3, further including a spring for biasing a first end of the rocker arms.

5. The socket of claim 3, wherein the rocker arms have surfaces for applying pressure to an integrated circuit.

6. The socket of claim 1, wherein the pressure application subassembly further includes truss members connected to the base.

7. The socket of claim 6 wherein the pressure application members are connected to the truss members.

8. The socket of claim 1, wherein the pressure application subassembly further includes a plurality of rocker arms for urging the pressure application members against an integrated circuit.

9. The socket of claim 6, wherein the pressure application members are pads.

10. The socket of claim 9, wherein the pads are removable.

11. The socket of claim 9, wherein the pads include at least one cavity and the rocker arms have first ends biased by a spring and second ends located in the cavities.

12. An integrated circuit socket, including:
a base;
a first plate connected to the base;
a pair of flexible arms connected to the first plate;
a second plate connected to the base; and
a latch subassembly movable between an open position and a closed position and wherein movement from the open position to the closed position causes the first and second plates and the arms to move so as to contact an integrated circuit in the socket, thereby positioning the integrated circuit.

13. The socket of claim 12, further including camming members connected to the base and wherein movement of the first plate in a first direction causes a portion of the arms to contact the camming members and move toward the integrated circuit.

14. The socket of claim 13, wherein the arms have ends and the ends are the portion that contact the camming members.

15. The socket of claim 12, further including a first pair of locators connected to the base and a second pair of locators connected to the second plate and wherein the second pair of locators contacts the integrated circuit as the latch subassembly is moved from the open position to the closed position.

16. The socket of claim 15, wherein the second pair of locators urge the integrated circuit into contact with the first pair of locators, thereby aligning the integrated circuit along one edge.

17. The socket of claim 12, wherein the arms contact the integrated circuit and align it about its centerline.

18. An integrated circuit socket, including:
first means for aligning an integrated circuit in the socket along one edge of the integrated circuit; and
second means for aligning the integrated circuit in the socket about the centerline of the integrated circuit.

19. The socket of claim 18, wherein the first means includes at least one moveable plate.

20. The socket of claim 18, wherein the first means includes a pair of stationary members.

21. The socket of claim 18, wherein the second means includes at least one flexible arm.

22. The socket of claim 18, wherein the second means includes at least one camming member.
